(19) United States
(12) Patent Application Publication
(10) Pub. No.: US 2010/0003511 A1
(43) Pub. Date: Jan. 7, 2010

(54) TRANSPARENT CONDUCTING ELECTRODE

(75) Inventor: Franky So, Gainesville, FL (US)

Correspondence Address: SALIWANCHIK LLOYD & SALIWANCHIK;A PROFESSIONAL ASSOCIATION, PO Box 142950, GAINESVILLE, FL, 32614, US

(73) Assignee: University of Florida Research Foundation, Inc., Gainesville, FL (US)

(21) Appl. No.: 12/497,057

(22) Filed: Jul. 2, 2009

Related U.S. Application Data
(60) Provisional application No. 61/078,098, filed on Jul. 3, 2008.

(51) Int. Cl. B32B 15/04; B05D 5/12; C23C 14/34

(52) U.S. Cl. 428/336; 427/108; 204/192.17; 264/104; 156/246; 428/469; 428/433; 428/337

(57) ABSTRACT

A transparent electrode multilayer film has at least one group III doped ZnO layer and at least one metal layer, where layers of doped ZnO alternate with metal layers. When a plurality of group III doped ZnO layers are present, the doped ZnO layers can have the same or different dopants and one or more dopants can be present in a doped ZnO layer. When a plurality of metal layers is present, the layers can be of the same or different metals, and a metal layer can be a single metal or a combination of two or more metals. The multilayer film can be free standing, but generally includes a substrate. Advantageous substrates are transparent and can be flexible for use as a flexible electrode. A method to form a transparent conductive multilayer film involves depositing at least one layer of a group III doped ZnO and at least one metal layer on a substrate.

### CROSS-REFERENCE TO RELATED APPLICATION(S)

The present application claims the benefit U.S. Provisional Application Serial No. 61/078,098, filed Jul. 3, 2008, which is hereby incorporated by reference herein in its entirety, including any figures, tables, or drawings.

### BACKGROUND OF THE INVENTION

Tin-doped indium-oxide (indium-tin oxide, ITO) is an n-type semiconductor with high carrier density (free carriers above 1×10²¹ cm⁻³) and wide band gap (optical gap above 3.8 eV). Thin films of ITO exhibit low-resistivity (1−3×10⁻⁴ Ωcm) and high optical transparency (>85%) in the visible wavelength region. Because of these properties, ITO films are used as transparent electrodes of devices such as flat panel displays. However, ITO films of about 100 nm display a sheet resistance of about 20 Ω/square and a transparency of about 80%, which is less than optimal for use as solar cells and light emitting diodes. Additionally, the world-wide supply of indium is rapidly depleting and the price of indium is anticipated to increase substantially.

ITO film properties are very dependent upon preparation techniques and the conditions employed. One important condition is the temperature of the substrate during deposition. Typically quality films that are highly conductive are polycrystalline where the substrate temperature is minimally 200° C. To deposit ITO on a polymer substrate, such as PET or polycarbonate, the substrate temperature must be low to avoid substrate deformation. Unfortunately, ITO films prepared on a room temperature substrate display a relatively poor resistivity of 5−7×10⁻⁴ Ωcm. Some compensation can be made by depositing a thicker ITO film, and films in excess of 500 nm display sheet resistance of about 10 Ω/sq. Such thick films are unattractive from the standpoint of cost and, more critically, because thick ITO films show poor optical transparency in the visible region.

This limitation of transparency has been addressed by preparing a three layer film where a thin silver layer is sandwiched between two ITO glass layers that are deposited at room temperature by sputtering, Sawada et al. J. Appl. Phys. 40 (2001) 3332-6. ITO/Ag/ITO films with a 15-nm-thick silver layer sandwiched by two 40-nm-thick ITO layers display a low sheet resistance (4.2 Ω/sq) and a high transmittance in the visible region.

In most cases, sputtering has been used in the fabrication of ITO films to achieve high reproducibility of film properties. Alternately, electron beam evaporation, thermal evaporation, chemical vapor deposition, spray pyrolysis, sol-gel processing, and pulsed laser deposition have been used for deposition of transparent conductive oxides (TCOs), however, sputtering is generally considered to be the most favorable deposition method.

As an alternate to ITO/Ag/ITO, more recently the examination of other metal oxide thin films with a silver layer has been carried out. ZnO has been substituted for ITO and has been found to produce a low resistance transparent electrode, Sahu et al. Appl. Surface Sci. 252 (2006) 7509-14. Although ZnO is an inferior conductor to ITO, the multilayer film can be formed at ambient temperatures and can display transmittance of more than 80% over the entire visible range and a sheet resistance as low as 3 Ω/sq.

Although useful transparent conductive films have been produced, the design films with even higher transparency and conductivity that combine or can be employed with a flexible substrate are desired for advanced transparent electrode applications.

### BRIEF SUMMARY OF THE INVENTION

Embodiments of the invention are directed to a transparent electrode multilayer film having at least one group III doped ZnO layers and at least one metal layer. The multilayer film has alternating layers of doped ZnO layers and metal layers and can include doped ZnO layers having the same or having different compositions. The differences in the compositions can include different dopant levels and dopant species, and can have multiple dopant species. The doped ZnO layers can be 10 to 100 nm in thickness. Different doped ZnO layers can have different thicknesses. The metal layer can be a single metal or a combination of metals. Different metal layers in the multilayer films can be different thicknesses, different metals and/or different combination of metals. The metal layers are sufficiently thick such that they are effectively continuous to provide the films with good electrical conductivity, yet are sufficiently thin to allow visible light transmission. The metal layers can be 3 to 20 nm thick. The group III dopant can have Al and/or Ga as the dopant. The metal layer can be formed from Ag, Au, Pd, Pt, Ti, V, Zn, Sn, Al, Co, Ni, Cu, Cr or any combination thereof. The multilayer film transmits visible light at 80% or greater and displays an electrical sheet resistance of less than or equal to 15 Ω/sq.

In general the transparent electrode multilayer film includes a substrate, generally one upon which the multilayer film is formed, although the multilayer film can be free standing. The substrate can be glass, inorganic polymer, organic polymer, ceramic, or metal. A flexible inorganic or organic polymer can be used as the substrate to form a flexible transparent electrode. The multilayer film having a single doped ZnO layer and a single metal layer, or any multilayer film where there are an equal number of doped ZnO and metal layers, can have either the metal or doped ZnO layer adjacent to the substrate. The outer layer can be a doped ZnO layer or a noble metal layer such that the multilayer film is resistant to oxidation in air, for a device using the transparent electrode requires such air oxidation resistance.

In another embodiment, a method to form the transparent conductive multilayer film described above includes steps of providing a substrate, depositing at least one layer of a group III doped ZnO, and depositing at least one metal layer, where the layers of doped ZnO alternate with the metal layers. The deposition steps can be performed by sputtering on a room temperature substrate. If, effectively, a free standing film is desired, the method can further include a step of removing the substrate by evaporation, dissolution, or decomposition of the substrate. If desired the multilayer film can be transferred from the substrate upon which it was deposited to the surface of a different, second substrate. The multilayer film can be placed on the second substrate and the first substrate can be removed. In this manner, the multilayer film can be formed under conditions that are not compatible with the direct deposition of the multilayer film on the desired substrate.

### BRIEF DESCRIPTION OF THE DRAWINGS

FIG. 1 shows a multilayer film including a substrate with two doped ZnO layers and a single metal layer according to an embodiment of the invention.

FIG. 2 shows a multilayer film including a substrate with one doped ZnO layers and a single metal layer adjacent to the substrate according to an embodiment of the invention.

FIG. 3 shows a free standing multilayer film of four doped ZnO layers and three metal layers according to an embodiment of the invention.

### DETAILED DESCRIPTION OF THE INVENTION

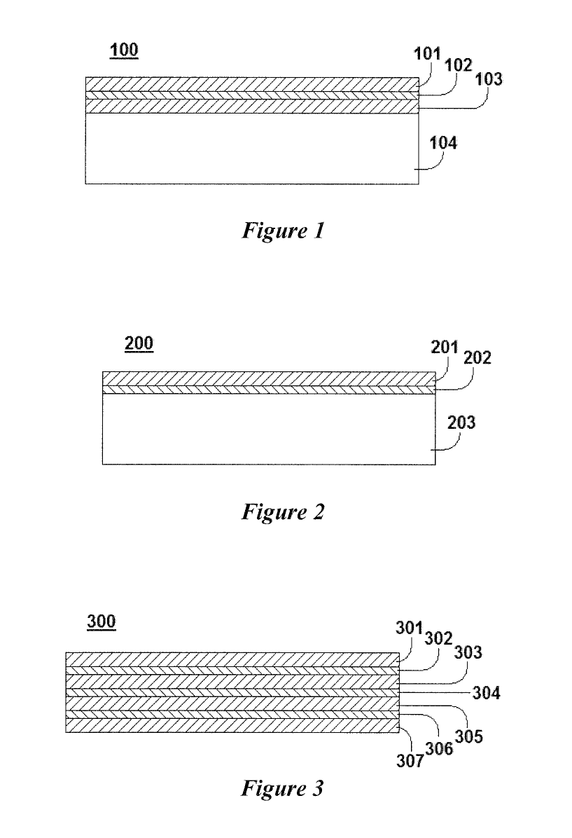

Embodiments of the invention are directed to a transparent electrode for use with optical devices such as liquid crystal displays (LCDs), plasma displays, solar cells, light emitting diodes (LED), organic light emitting diodes (OLED) and other devices. The transparent electrode has a multilayer film structure that includes at least one group III doped ZnO film and at least one metal layer. For example, the group III dopant can be Al or Ga to yield an Al doped ZnO or Ga doped ZnO layer, respectively. A group III doped ZnO layer can include more than one different group III dopant and can include other dopants with the group III dopants. The multilayer films have alternating doped ZnO and metal layers in their structure and, generally but not necessarily, a substrate is included upon which the multiple film layers are formed. The multilayer film can be indicated as follows for a three-layer film where a metal layer, for example a silver layer, is situated between two doped ZnO layers, for example an Al doped ZnO layer: AlZnO/Ag/AlZnO. An example of such a three-layer film 100 on a substrate 104 is shown in FIG. 1. In many embodiments, the film 100 has doped ZnO layers 101, 103 on the top and bottom of the metal layer 102; however, particularly where the metal layer comprises a noble metal that is resistant to oxidation, a metal layer can be the top layer, bottom layer, or both of the multilayer film. FIG. 2 illustrates a two-layer film 200 where the doped ZnO layer 201 is at an air interface and a metal layer 202 is adjacent a substrate 203. Multilayer films with four or more layers are possible, as long as the combined multilayer film is sufficiently transparent and electrically conductive. A free standing seven-layer film 300 with doped ZnO layers 301 and 307 on both faces with two ZnO layers 303 and 305 situated between the three metal layers 302, 304, and 306 is illustrated in FIG. 3. According to embodiments of the invention, multilayer film having a plurality of metal layers, for example, three or more silver layers, can display very high conductivities.

The metal must be one where electrically conductive films can be formed with dimensions that permit a low absorbance of light and can be formed, generally but not necessarily, by an evaporative method including, but not restricted to, a sputtering method. A nonexclusive list of metals that can be used include Ag, Au, Pd, Pt, Ti, V, Zn, Sn, Al, Co, Ni, Cu, and Cr. The metal can be a metal alloy of two or more metals that can be co-deposited.

In many embodiments of the invention, the substrate is a transparent substrate, such as a glass or a polymer. The polymer can be an organic polymer or an inorganic polymer and can be a plastic, rubber, or cured resin. The polymer can be a homopolymer or copolymer of any architecture. For example the homopolymer can be crystalline or amorphous, stereorandom or stereoregular, and the copolymer can be random, alternating, block, graft or have any other structure. The substrate can be opaque and can be a ceramic or metal. In one embodiment of the invention, an effectively free standing film, without a substrate upon which the multilayer film is constructed, can be prepared by formation of the multilayer film on a substrate that can be removed subsequently by evaporation, dissolution, chemical degradation, or any other method. The removal of the substrate can be carried out after deposition of the multilayer film on another surface, which can be of a solid or a liquid.

The multilayer films can be an ensemble of doped ZnO layers of the same or different thicknesses and metal layers of the same or different thickness. The doped ZnO layers independently can have a thickness of about 10 nm to about 100 nm. In one embodiment of the invention the thickness of the group III ZnO layer is less than 50 nm. Thick group III doped ZnO layers can have surface roughness that can vary by the method of formation of the layer. Thicker layers can have a high surface roughness of sufficient dimensions to cause light scattering that negatively affects transmission of light through the film. The metal layer can have a thickness of about 3 to about 20 nm. The metal layer is 4 nm to 10 nm in embodiments of the invention. At lower thickness, for example a sputtered 2 nm layer, the metal layer can be non-continuous, having, in the lower limits, islands of metal separated from each other resulting in a metal layer that has higher electrical resistance. Hence, it is desired that the metal layer is of sufficient thickness that the layer is effectively continuous. The multilayer films can be an ensemble of doped ZnO layers having different dopants and different metal layers.

The inventive multilayer film transparent electrodes can be prepared by providing a substrate, and sequentially depositing group III doped ZnO layers and metal layers on top of the substrate. Either a doped ZnO layer or a metal layer can be deposited on the substrate. The layers can be deposited by electron beam evaporation, thermal evaporation, chemical vapor deposition, spray pyrolysis, sol-gel processing, pulsed laser deposition, electroplating, sputtering or any other method, where some methods are appropriate for the doped ZnO layer deposition, some are appropriate for the metal layer deposition, and some are appropriate for depositing either layer, as can be appreciated by one skilled in the art. Sputtering is a method that enables the deposition of both layers by varying the targets, where the substrate for film layer formation can reside in a deposition chamber throughout the formation of the entire multilayer film. Sputtering also allows for the deposition to occur at room temperature or slightly elevated temperatures. Room temperature sputtering methods that can be applied to the preparation of group III doped ZnO include, but are not limited to, RF magnetron sputtering of Group III oxide in ZnO targets and dc magnetron sputtering of Zn and a group III metal in an O₂—Ar atmosphere. Room temperature sputtering of Ag or other metals can include, but is not limited to, dc magnetron sputtering of the metal.

Because sputtering can be carried out at or near room temperature conditions, various polymer supports can be used. Polymeric supports that can be used for the transparent electrodes of the present invention include, but are not exclusive to, polyvinylidene fluoride, vinylidene fluoride-propylene fluoride copolymer, cyanoethylcellulose, polyethylene terephthalate, polycarbonate, polyvinylchloride, polyethylene, polypropylene, polyamides, and cellulose acetate. In many embodiments of the invention, the polymeric substrate is a part of the transparent electrode and provides strength and flexibility. In other embodiments, the polymeric substrate does not provide material properties necessary to the fabricated device other than transparency and, alternately, many other, less mechanically robust, polymers can be employed. When a free standing film is desired, a polymeric or other substrate may be chosen based on the ability to remove the substrate due to it solubility, volatility, or ability to be decomposed chemically or physically. Such a free standing multilayer film can be transferred to a surface of another substrate before or after removal of the substrate used for the deposition of the layers.

All patents, patent applications, provisional applications, and publications referred to or cited herein, supra or infra, are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

We claim:

1. A transparent electrode multilayer film comprising at least one group III doped ZnO layer and at least one metal layer.

2. The multilayer film of claim 1, further comprising a substrate.

3. The multilayer film of claim 2, wherein said substrate comprises glass, inorganic polymer, organic polymer, ceramic, or metal.

4. The multilayer film of claim 3, wherein said substrate comprises a flexible inorganic or organic polymer.

5. The multilayer film of claim 1, wherein the dopant of said group III doped ZnO layer comprises Al, Ga or any combination of Al and Ga.

6. The multilayer film of claim 1, wherein said metal comprises Ag, Au, Pd, Pt, Ti, V, Zn, Sn, Al, Ni, Cu, Co, Cr, or any combination thereof.

7. The multilayer film of claim 1, wherein said metal comprises Ag.

8. The multilayer film of claim 1, comprising a plurality of said metal layers, wherein said metal comprises Ag.

9. The multilayer film of claim 1, wherein said doped ZnO layers are 10 to 100 nm in thickness.

10. The multilayer film of claim 1, wherein said metal layers are 3 to 20 nm in thickness.

11. The multilayer film of claim 1, wherein transmittance to visible light is greater than or equal to 80%.

12. The multilayer film of claim 1, wherein electrical sheet resistance is less than or equal to 15 Ω/sq.

13. The multilayer film of claim 1, wherein said multilayer film comprises one of said doped ZnO layers and one of said metal layers.

14. The multilayer film of claim 13, wherein said metal layer is interposed between a substrate and said doped ZnO layer.

15. The multilayer film of claim 13, wherein said doped ZnO film is interposed between a substrate and said metal layer.

16. The multilayer film of claim 15, wherein said metal layer is a noble metal layer.

17. The multilayer film of claim 1, wherein said multilayer film comprises one of said metal layers interposed between two of said doped ZnO layers.

18. A method to form a transparent conductive multilayer film comprising the steps of:
providing a substrate;
depositing at least one layer of a group III doped ZnO; and
depositing at least one metal layer, wherein said layers of doped ZnO alternate with said metal layers.

19. The method of claim 18, wherein said steps of depositing comprise steps of sputtering.

20. The method of claim 18, wherein said steps of depositing are performed at about room temperature.

21. The method of claim 18, wherein the dopant of said group III doped ZnO layer comprises Al, Ga or any combination of Al and Ga.

22. The method of claim 18, wherein said metal comprises Ag, Au, Pd, Pt, Ti, V, Zn, Sn, Al, Ni, Cu, Co, Cr, or any combination thereof.

23. The method of claim 18, wherein said substrate comprises glass, inorganic polymer, organic polymer, ceramic, or metal.

24. The method of claim 18, further comprising the step of removing said substrate.

25. The method of claim 24, wherein said removing step comprises evaporating, dissolving, or decomposing.

26. The method of claim 25, further comprising the step of transferring said multilayer film to a surface of a second substrate.
